(19) United States
(12) Patent Application Publication
(10) Pub. No.: US 2016/0262269 A1
(43) Pub. Date: Sep. 8, 2016

(54) COPPER ETCHING METHOD FOR MANUFACTURING CIRCUIT BOARD

(71) Applicant: KINSUS INTERCONNECT TECHNOLOGY CORP., Taoyuan (TW)

(72) Inventors: Ting-Hao Lin, Taipei (TW); Chiao-Cheng Chang, Taoyuan City (TW); Yi-Nong Lin, Keelung City (TW)

(21) Appl. No.: 14/640,993

(22) Filed: Mar. 6, 2015

(51) Int. Cl. H05K 3/18; H05K 3/06

(52) U.S. Cl. CPC H05K 3/188; H05K 3/064

(57) ABSTRACT

Disclosed is a copper etching method for manufacturing a circuit board, including steps of electroplating a metal copper support layer, coating a thermal sensitive photo resist layer, coating a photo resist layer, performing a process of pattern transfer, removing part of the photo resist layer to form a photo resist pattern, electroplating a metal copper layer to form a circuit pattern, peeling off the photo resist layer, pressing a stacked body composed of a stacked substrate and a stacked material layer onto the circuit pattern to embed the circuit pattern in the stacked material layer, removing the base layer, performing a copper etching process to removing the metal copper support layer, and removing the thermal sensitive photo resist layer to expose the circuit pattern. In particular, the circuit pattern protrudes from the stacked material layer so as to facilitate the subsequent process of forming solder balls.

### BACKGROUND OF THE INVENTION

1. Field of the Invention

The present invention relates generally to a method for manufacturing a circuit board, and more specifically to a copper etching method employing a thermal sensitive photo resist layer as a copper etching stop layer such that a circuit pattern under a metal copper support layer is not etched by a copper etching agent upon removing the metal copper support layer by copper etching, thereby preventing the circuit pattern from being lower than the surface of the stacked material layer and facilitating the subsequent packaging process for solder balls.

2. The Prior Arts

Circuit boards have been widely used in various electronic products because electronic elements can be easily placed and connected together so as to exhibit preset electrical functions.

In the prior arts, the process flow of manufacturing a circuit board is shown in FIG. 1 and specifically comprises the corresponding processing steps sequentially performed. In FIG. 1(A), a metal copper support layer 12 is electroplated on a base layer 10. Next, a photo resist layer 14 is coated on the metal copper support layer 12 and then partly removed to expose the corresponding metal copper support layer 12 so as to form a photo resist pattern, as shown in FIG. 1(B). A metal copper layer is electroplated to cover the exposed part of the metal copper support layer 12 in the photo resist pattern so as to form a circuit pattern 16, as shown in FIG. 1(C). The photo resist layer 14 is then removed, and a stacked body T composed of a stacked material layer 18 and a stacked substrate 19 is pressed onto the circuit pattern 16 such that the circuit pattern 16 is embedded in the stacked material layer 18, as shown in FIG. 1(D). Finally, the base layer 10 is removed and the metal copper support layer 12 is etched to expose the circuit pattern 16, as shown in FIG. 1(E).

However, one of the drawbacks in the prior arts is that when the metal copper support layer is etched to expose the circuit pattern, the metal copper support layer may suffer further etching such that the circuit pattern closely attached to the metal copper support layer is also etched and thus lower than the surface of the stacked material layer, as shown by the area A in FIG. 1(E), especially the locally magnifying area B. As a result, the latter packaging process of solder balls may fail because the connection pads or the solder balls formed are not completely connected to the circuit pattern to cause the serious problem of free welding or solder skip.

Therefore, it is greatly needed to provide a new copper etching method for manufacturing a circuit board. The thermal sensitive photo resist layer coated on the metal copper support layer is used as the stop layer as in the copper etching method such that the circuit pattern formed on the thermal sensitive photo resist layer is protected by the stop layer when the metal copper support layer is removed in the latter copper etching treatment. As a result, the circuit pattern is prevented from being lower than the surface of the stacked material layer, thereby overcoming the above problems in the prior arts.

### SUMMARY OF THE INVENTION

A primary objective of the present invention is to provide a copper etching method for manufacturing a circuit board. Specifically, the copper etching method of the present invention comprises the sequential processing steps of electroplating a metal copper support layer, coating a thermal sensitive photo resist layer, coating a photo resist layer, performing a process of pattern transfer, removing part of the photo resist layer to form a photo resist pattern, electroplating a metal copper layer to form a circuit pattern, peeling off the photo resist layer, pressing a stacked body composed of a stacked substrate and a stacked material layer onto the circuit pattern to embed the circuit pattern is in the stacked material layer, removing the base layer, removing the metal copper support layer by a copper etching process to expose the thermal sensitive photo resist layer, and removing the thermal sensitive photo resist layer to expose the circuit pattern.

Since the thermal sensitive photo resist layer is formed between the circuit pattern and the metal copper support layer, the circuit pattern is controlled by the thickness of the thermal sensitive photo resist layer when the metal copper support layer is removed by the copper etching agent. As a result, the circuit pattern is prevented from being lower than the surface of the stacked material layer. In other words, the circuit pattern protrudes from the stacked material layer. Therefore, the copper etching method of the present invention greatly facilitates the subsequent packaging process for solder balls, and the connection pads or the solder balls are completely connected to the circuit pattern to avoid the problem of free welding or solder skip in the prior arts.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a view showing the method for manufacturing a circuit board in the prior arts;

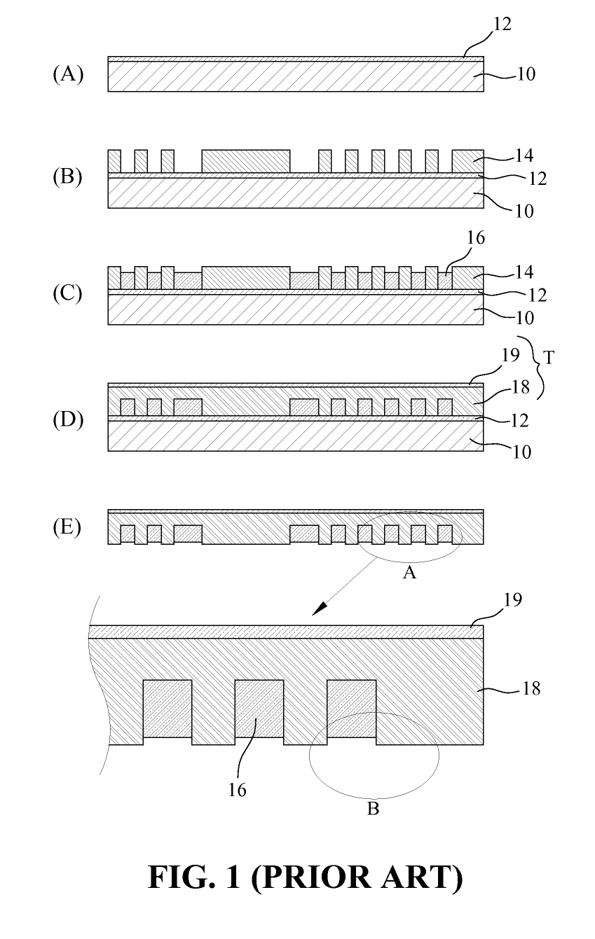

FIG. 2 is a flowchart showing a copper etching method for manufacturing a circuit board according to one embodiment of the present invention; and

FIG. 3 is a view showing the copper etching method of the present invention.

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

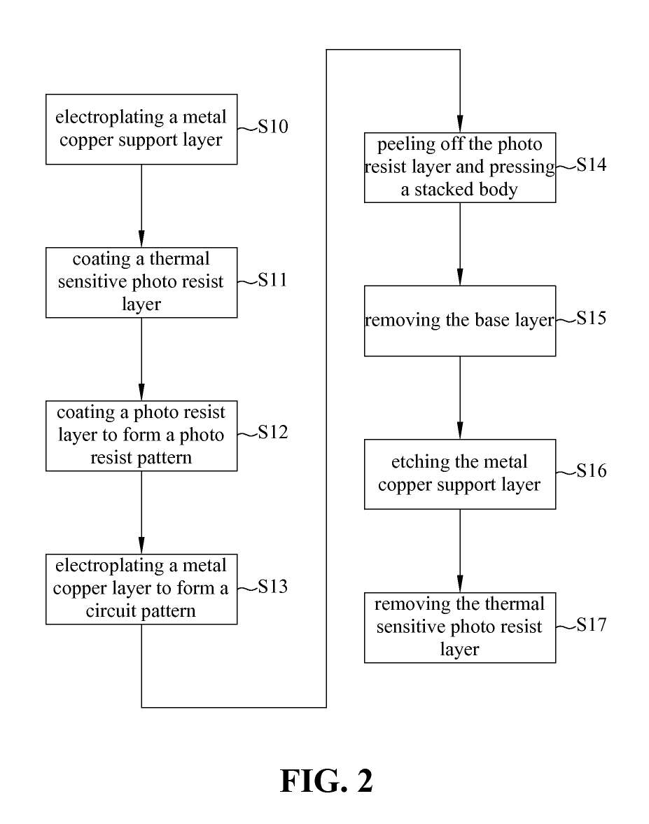

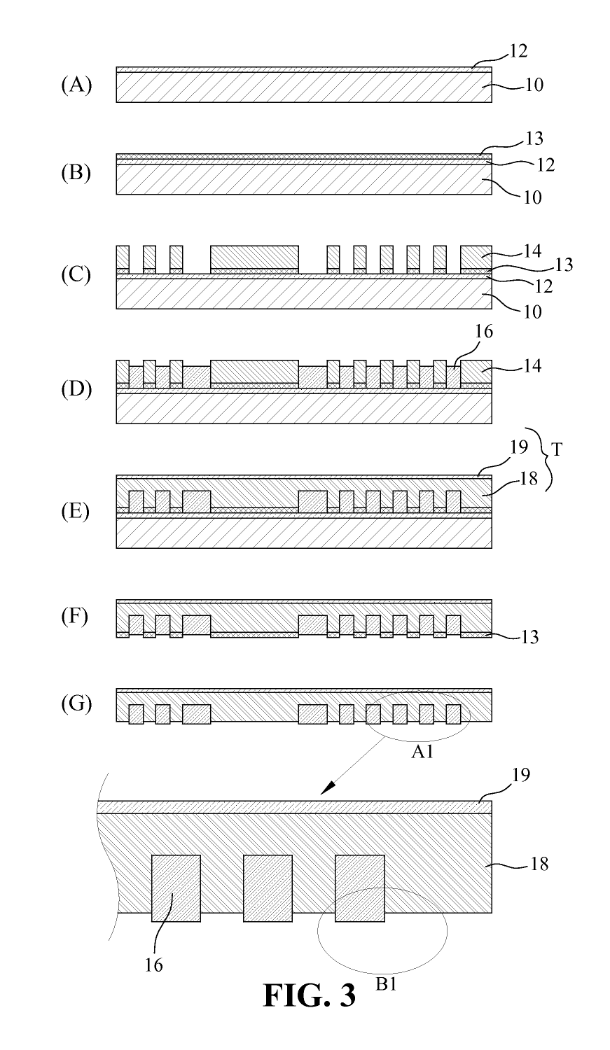

Please refer to FIGS. 2 and 3 showing a flowchart and the corresponding view of the copper etching method for manufacturing a circuit board according to one embodiment of the present invention, respectively. As shown in FIGS. 2 and 3, the copper etching method according to the embodiment of the present invention generally comprises steps S10, S11, S12, S13, S14, S15, S16 and S17 for performing a copper etching treatment on the circuit board.

First, the copper etching method of the present invention starts at the step S10, in which a metal copper support layer 12 is formed on a base layer 10 by electroplating, as shown in FIG. 3(A). Then, the step S11 is performed by coating a thermal sensitive photo resist layer 13 on the metal copper support layer 12, as shown in FIG. 3(B). In particular, the thermal sensitive photo resist layer 13 does not react with the copper etching agent. In step S12, a photo resist layer 14 is coated on the thermal sensitive photo resist layer 13, a process of pattern transfer is performed on the photo resist layer 14, and part of the photo resist layer 14 is removed to expose the corresponding part of the thermal sensitive photo resist layer 13 so as to form a photo resist pattern, as shown in FIG. 3(C).

Next, in the step S13, a metal copper layer 16 is formed by electroplating to cover the exposed thermal sensitive photo resist layer 13, as shown in FIG. 3(D). Enter the step S14, in which the photo resist layer 14 is peeled off, and a stacked body T composed of a stacked material layer 18 and a stacked substrate 19 is pressed onto the circuit pattern 16 such that the circuit pattern 16 is embedded in the stacked material layer 18, as shown in FIG. 3(E).

In the step S15, the base layer 10 is removed, and then in step S16, a copper etching process is performed to removing the metal copper support layer 12 so as to expose the thermal sensitive photo resist layer 13 under the metal copper support layer 12, as shown in FIG. 3(F). Finally, the thermal sensitive photo resist layer 13 is removed to expose the circuit pattern 16 in step S17, as shown in FIG. 3(G). More specifically, a magnifying area A1, especially the local magnifying area B1, clearly illustrates that the circuit pattern 16 protrudes from the surface of the stacked material layer 18.

Specifically, the stacked material layer 18 is formed of a plastic material and the plastic material preferably comprises polypropylene (PP). Additionally, the copper etching agent used in the method of the present invention may comprise ferric chloride, ammonium persulfate, sulfuric acid-hydrogen peroxide, hydrochloric acid-hydrogen peroxide, ammonium chloride-sodium chlorate-hydrochloric acid, or copper chloride-sodium chlorate-ammonium chloride-hydrochloric acid.

From the above mention, one primary feature of the present invention is that the thermal sensitive photo resist layer does not react with the copper etching agent and is configured between the circuit pattern and the metal copper support layer such that the circuit pattern is controlled by the thickness of the thermal sensitive photo resist layer upon removing the metal copper support layer by the copper etching agent, thereby preventing the circuit pattern from being lower than the surface of the stacked material layer. Therefore, the copper etching method of the present invention may facilitate the subsequent packaging process for solder balls such that the connection pads or the solder balls are completely connected to the circuit pattern.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A copper etching method for manufacturing a circuit board, comprising:
electroplating a metal copper support layer on a base layer;
coating a thermal sensitive photo resist layer on the metal copper support layer;
coating a photo resist layer on the thermal sensitive photo resist layer, performing a process of pattern transfer, removing part of the photo resist layer, and exposing the corresponding part of the thermal sensitive photo resist layer to form a photo resist pattern;
electroplating a metal copper layer to cover the exposed thermal sensitive photo resist layer to form a circuit pattern;
peeling off the photo resist layer, and pressing a stacked body composed of a stacked substrate and a stacked material layer onto the circuit pattern such that the circuit pattern is embedded in the stacked material layer;
removing the base layer;
performing a copper etching process to etch and remove the metal copper support layer to expose the thermal sensitive photo resist layer; and
removing the thermal sensitive photo resist layer to expose the circuit pattern protruding from a surface of the stacked material layer.

2. The copper etching method as claimed in claim 1, wherein the stacked material layer is formed of a plastic material and the plastic material comprises polypropylene.

3. The copper etching method as claimed in claim 1, wherein the copper etching process employs a copper etching agent comprising ferric chloride, ammonium persulfate, sulfuric acid-hydrogen peroxide, hydrochloric acid-hydrogen peroxide, ammonium chloride-sodium chlorate-hydrochloric acid, or copper chloride-sodium chlorate-ammonium chloride-hydrochloric acid.
